(19) United States
(12) Patent Application Publication
(10) Pub. No.: US 2018/0035551 A1
(43) Pub. Date: Feb. 1, 2018

(54) PRINTED CIRCUIT BOARD AND SEMICONDUCTOR MEMORY DEVICE INCLUDING THE SAME

(71) Applicant: Samsung Electronics Co., Ltd., Suwon-si (KR)

(72) Inventor: Jung-hyun Woo, Hwaseong-si (KR)

(73) Assignee: Samsung Electronics Co., Ltd., Suwon-si (KR)

(21) Appl. No.: 15/428,292

(22) Filed: Feb. 9, 2017

(30) Foreign Application Priority Data
Jul. 29, 2016 (KR) 10-2016-0097027

(51) Int. Cl. H05K 5/00; G11C 5/04; F16B 43/00; H05K 1/11

(52) U.S. Cl. CPC H05K 5/006; H05K 1/117; H05K 5/0008; G11C 5/04; F16B 43/004; H05K 2201/09063; H05K 2201/10159; H05K 2201/10409; H05K 2201/10265

(57) ABSTRACT

A semiconductor memory device including a case including an upper case, a lower case, support structures extending from the lower case to the upper case, a printed circuit board (PCB) in the case and supported by the support structures, a leaf spring on a lower surface of the PCB, the leaf spring seated on support surfaces of the support structures, and a solder layer between the PCB and the leaf spring, the solder layer coupling the PCB with the leaf spring may be provided.

### CROSS-REFERENCE TO RELATED APPLICATION

This application claims priority under 35 U.S.C. §119 to Korean Patent Application No. 10-2016-0097027, filed on Jul. 29, 2016, in the Korean Intellectual Property Office, the disclosure of which is incorporated herein in its entirety by reference.

### BACKGROUND

The inventive concepts relate to printed circuit boards (PCBs) and/or semiconductor memory devices including the PCB.

A hard disk drive (HDD) has been widely used as a memory device for storing high capacity information. Recently, the HDD is being gradually replaced with a semiconductor memory device (e.g., solid state drive (SSD)) using a non-volatile memory element.

The semiconductor memory device includes, for example, a printed circuit board (PCB) and a connector coupled to one side of the PCB and transmitting data to an external device. The PCB and the connector have various standards and different shapes or dimensions according to types. Accordingly, a case is separately manufactured according to standards of the PCB and/or the connector configurations.

### SUMMARY

The inventive concepts provide printed circuit boards (PCBs) with enhanced rigidity and/or semiconductor memory devices including the PCB.

The inventive concepts also provide semiconductor memory devices that use the same connector even though a PCB has different thicknesses.

According to an aspect of the inventive concepts, a printed circuit board (PCB) includes a body, at least one leaf spring coupled to the body, and a solder layer between the body and the at least one leaf spring, the solder layer coupling the at least one leaf spring with the body.

According to another aspect of the inventive concepts, a semiconductor memory device includes a case, a PCB installed in the case, at least one leaf spring coupled onto a lower surface of the PCB, and a solder layer interposed between the PCB and the at least one leaf spring, the solder layer coupling the PCB with the at least one leaf spring.

According to still another aspect of the inventive concepts, a semiconductor memory device includes a case including an upper case, a lower case, and support structures extending from the lower case to the upper case, a PCB installed in the case and supported by the support structures, a leaf spring mounted on a lower surface of the PCB and seated on support surfaces of the support structures, and a solder layer interposed between the PCB and the leaf spring, and the solder layer coupling the PCB with the leaf spring.

According to yet another aspect of the inventive concepts, a semiconductor memory device includes a case including a supporting structure, the supporting structure extending from one surface of the case, a PCB in the case, the PCB including a top surface and a bottom surface, the top surface of the PCB having a semiconductor device thereon, the bottom surface of the PCB facing and supported by the support structure, a leaf spring between the bottom surface of the PCB and the support structure, the leaf spring has a first portion vertically overlapping the support structure and a second portion vertically not overlapping the support structure, and a solder layer between the PCB and the second portion of the leaf spring, the solder layer coupling the PCB with the leaf spring.

### BRIEF DESCRIPTION OF THE DRAWINGS

Example embodiments of the inventive concepts will be more clearly understood from the following detailed description taken in conjunction with the accompanying drawings in which:

FIG. 1 is a schematic perspective view of a semiconductor memory device according to an example embodiment;

FIGS. 2A and 2B are plan views of an upper surface and a lower surface of a printed circuit board (PCB) of FIG. 1, respectively;

FIG. 3 is a perspective view of a leaf spring of FIG. 2B;

FIG. 4 is a cross-sectional view of the semiconductor memory device taken along a line IV-IV′ of FIG. 1;

FIG. 5 is a cross-sectional view of the semiconductor memory device taken along a line V-V′ of FIG. 1;

FIG. 6 is a plan view of a leaf spring according to an example embodiment;

FIG. 7 is a cross-sectional view of the semiconductor memory device taken along a line IV-IV′ of FIG. 1;

FIG. 8 is a cross-sectional view of the semiconductor memory device taken along a line V-V′ of FIG. 1;

FIG. 9 is a plan view of a leaf spring according to an example embodiment;

FIG. 10A is a plan view of a leaf spring according to an example embodiment;

FIG. 10B is a cross-sectional view of a support plate of the leaf spring of FIG. 10A;

FIG. 11 is a plan view of a leaf spring according to an example embodiment;

FIG. 12 is a plan view of a lower surface of a PCB according to an example embodiment;

FIG. 13 is a perspective view of a leaf spring of FIG. 12;

FIG. 14 is a cross-sectional view of the PCB taken along a line XIV-XIV′ of FIG. 12;

FIG. 15 is a schematic perspective view of a semiconductor memory device according to an example embodiment;

FIG. 16 is a cross-sectional view of the semiconductor memory device taken along a line XVI-XVI′ of FIG. 15;

FIG. 17 is a cross-sectional view of the semiconductor memory device taken along a line XVI-XVI′ of FIG. 15 according to s an example embodiment;

FIG. 18 is a cross-sectional view of the semiconductor memory device taken along a line XVI-XVI′ of FIG. 15 according to an example embodiment;

FIG. 19 is a plan view of a PCB according to an example embodiment; and

FIG. 20 is a cross-sectional view of a part of a semiconductor memory device according to an example embodiment.

### DETAILED DESCRIPTION

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present.

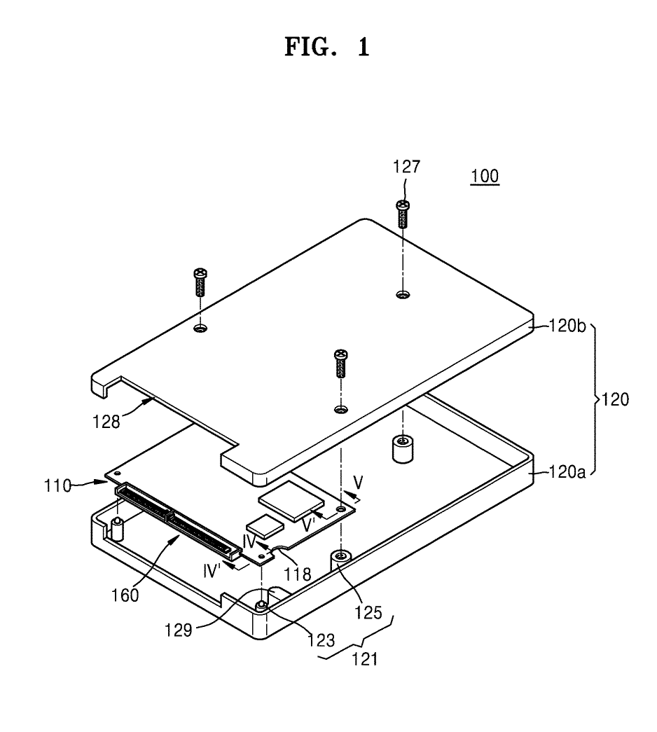

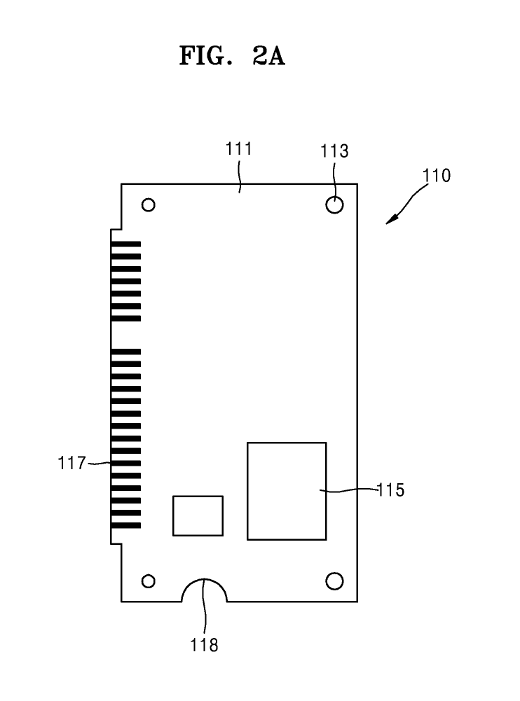

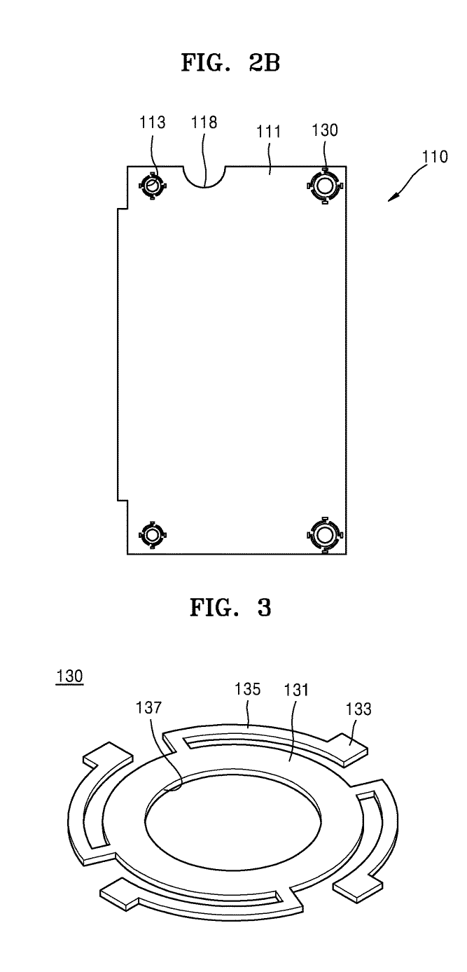

FIG. 1 is a schematic perspective view of a semiconductor memory device 100 according to an example embodiment. FIGS. 2A and 2B are plan views of an upper surface and a lower surface of a printed circuit board (PCB) 110 of FIG. 1, respectively.

Referring to FIGS. 1 through 2B, the semiconductor memory device 100 may include a case 120, the PCB 110 installed in the case 120, leaf springs 130 mounted on a surface of the PCB 110, and a connector 160 coupled to one side of the PCB 110.

The PCB 110 may include at least one semiconductor device 115 mounted on one surface thereof or may include connector terminals 117 arranged along one edge thereof. The PCB 110 may be a rigid PCB or a flexible PCB. In more detail, the PCB may include a body 111 forming an exterior thereof. The body 111 may include a base substrate (not shown), wirings (not shown), an upper protection layer (not shown), and a lower protection layer (not shown). The wirings included in the body 111 may connect the semiconductor device 115 and/or other active and passive elements.

The semiconductor device 115 may be mounted on the PCB 110 by using, for example, a surface mounting method and/or an insertion mounting method. In more detail, the semiconductor device 115 may be mounted on the PCB 110 by using a ball grid array (BGA) method, a pin grid array (PGA) method, a tape carrier package (TCP) method, a chip-on-board (COB) method, a quad flat package (QFP) method, a quad flat non-leaded (QFN) method, etc. However, a method of mounting the semiconductor device 115 on the PCB 110 is not limited thereto.

The semiconductor device 115 may be a logic package that performs a logic calculation or may be a memory package. The logic package may be, for example, a memory controller. The memory package may be, for example, a non-volatile memory. The non-volatile memory may be a flash memory, a phase-change RAM (PRAM), a resistive random-access memory (RRAM), a ferroelectric RAM (FeRAM), a magnetic RAM (MRAM), etc. but is not limited thereto. The flash memory may be, for example, a NAND flash memory. The memory package may be, for example, a volatile memory. The volatile memory may be, for example, a dynamic random-access memory (DRAM), a static RAM (SRAM), a synchronous DRAM (SDRAM), or a high bandwidth memory (HBM) DRAM, etc. However, the semiconductor device 115 is not limited thereto and may include various types of semiconductor devices manufactured based on a semiconductor substrate.

The connector terminals 117 may be plated with a conductor, for example, copper and/or gold. The connector terminals 117 may be arranged at an equivalent interval or at different intervals. The connector terminals 117 may have the same side or different sizes.

The connector terminals 117 may be electrically connected to the semiconductor device 115 through the wirings formed in the body 111 of the PCB 110. The connector terminals 117 may include power terminals and/or signal terminals and may include terminals that enable communication with an external device.

The connector 160 may be coupled to one side of the PCB 110 and may be electrically connected to the PCB 110. The connector 160 may be arranged in one edge of the PCB 110 in which the connection terminals 117 are arranged. The connector 160 may include a plurality of connector pins that are electrically connected to the connection terminals 117 of the PCB 110 through internal wirings (not shown) of the connector 160.

The case 120 may accommodate the PCB 110 therein. For example, the case 120 may include an upper case 120b and a lower case 120a and may have the PCB 110 installed between the upper case 120b and the lower case 120a. The case 120 may include an opening 128 that exposes the connector 160 coupled to the PCB 110 to the outside. Thus, the connector pins of the connector 160 may be exposed to the outside through the opening 128.

The case 120 may include support structures 121 provided to support the PCB 110. The PCB 110 may be placed on the support structures 121. The support structures 121 may extend from one surface of the lower case 120a to the upper case 120b. The support structures 121 may be arranged to correspond to pin holes 113 of the PCB 110.

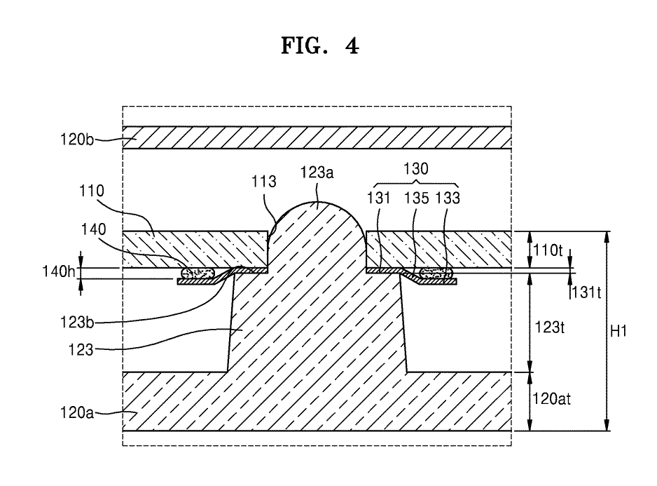

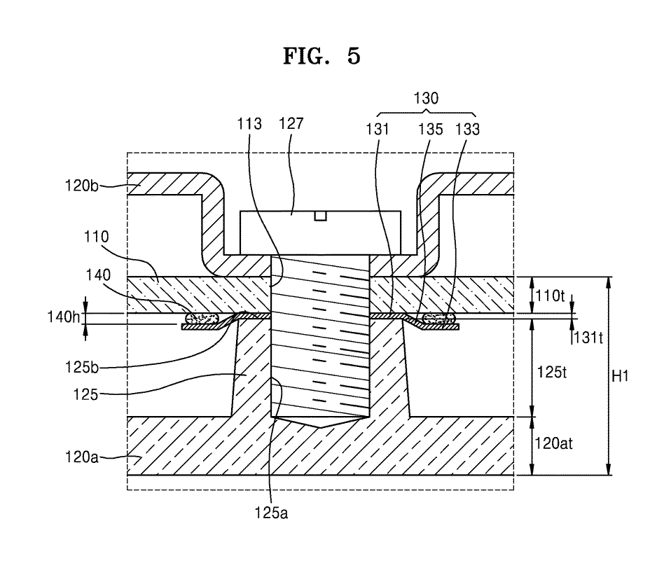

For example, the support structures 121 may include first support structures 123 each having an upper portion 123a of FIG. 4 inserted into some of the pin holes 113 of the PCB 110 and second support structures 125 each having a cavity or recess 125a of FIG. 5 into which a fastening device 127 (e.g., a screw) that passes through the pin holes 113 of the PCB 110 may be inserted. The first support structures 123 and the second support structures 125 will be described in more detail below.

The lower case 120a may have a protrusion portion 129 protruding from side walls thereof toward inside to easily install the PCB 110. The protrusion portion 129 may have a shape corresponding to a concave portion 118 formed on one side of the PCB 110. The PCB 110 may be arranged in the case 120 such that the protrusion portion 129 is fitted into the concave portion 118 of the PCB 110. That is, before the PCB 110 is fixed to the case 120 through the fastening device 127 (e.g., a screw) the protrusion portion 129 and the concave portion 118 may enable the PCB 110 to be easily arranged in a set location.

The case 120 may include a metallic material or a thermosetting or thermoplastic plastic material. Alternatively, the case 120 may include a composite material of metal and plastic. The metallic material may be, for example, aluminum (Al), copper (Cu), titanium (Ti), or an alloy containing one of these, or stainless steel but is not limited thereto. The plastic material may be, for example, polystyrene, polypropylene, acrylonitrile-butadiene-styrene (ABS), polycarbonate, polyethylene terephthalate, polybutylene terephthalate, polymethyl (meth) acrylate, polyester, polyvinyl chloride, polyphenylene ether, polyacetal-based resin such as poly oxymethylene, copolymer thereof, or a mixture thereof but is not limited thereto.

The leaf spring 130 may be coupled to the PCB 110. As shown in FIG. 2B, a plurality of leaf springs 130 may be placed on a lower surface of the PCB 110. The leaf spring 130 may be fastened to the PCB 110 by using a surface mounting method. For example, a solder layer 140 of FIG. 4 that will be described below may be interposed between the leaf spring 130 and the PCB 110.

The leaf spring 130 may include a metallic material (e.g., iron, or aluminum) or may include a plastic material (e.g., a polyimide film). In some example embodiments, the leaf spring 130 may include a composite material of metal and plastic.

The semiconductor memory device 100 may be, for example, a solid state disk (SSD), a computer, a Ultra Mobile Personal Computer (UMPC), a workstation, a net-book, a Personal Digital Assistants (PDA), a portable computer, a web tablet, a tablet computer, a wireless phone, a mobile phone, a smart phone, an e-book, a portable multimedia player (PMP), a portable game device, a navigation device, a black box, a digital camera, Digital Multimedia Broadcasting (DMB) player, a 3-dimensional television, a smart television, a digital audio recorder, a digital audio player, a digital picture recorder, a digital picture player, a digital video recorder, a digital video player, a storage constituting a data center, a device transmitting and receiving information in a wireless environment, one of various electronic devices constituting a computer network, one of various electronic devices constituting a telematics network, an RFID device, or one of various components constituting a computing system.

FIG. 3 is a perspective view of the leaf spring 130 of FIG. 2B.

Referring to FIG. 3, the leaf spring 130 may include a support plate 131, at least one pad 133, and at least one hinge 135.

The support plate 131 may include a through hole 137 that vertically penetrates therethrough. The leaf spring 130 may be fastened to the PCB 110 of FIG. 2B such that the through hole 137 is connected to the pin hole 113 of FIG. 2B of the PCB 110.

The pad 133 may be placed in a peripheral direction of the support plate 131, and may provide one surface on which a solder layer 140 of FIG. 4 is arranged.

The hinge 135 may connect the support plate 131 with the pad 133 placed in the peripheral direction of the support plate 131. One end of the hinge 135 may be connected to an edge of the support plate 131 and another end thereof may be connected to the pad 133. The hinge 135 may extend along at least a part of the edge of the support plate 131.

The hinge 135 may be bent in a first direction when force is applied toward the pad 133. In such case, the hinge 135 may apply a desired (or alternatively, predetermined) resilience in a second direction opposite to the first direction. The leaf spring 130 may be a flexible leaf spring including the hinge 135 that is bendable.

As shown in FIG. 3, the support plate 131 may have a circular shape when viewed from above but the shape of the support plate 131 is not limited thereto. In some example embodiments, the support plate 131 may have a polygonal shape (e.g., a triangular shape, a rectangular shape, or an oval shape).

As shown in FIG. 3, the through hole 137 may have a circular shape when viewed from above but the shape of the through hole 137 is not limited thereto. In some example embodiments, the through hole 137 may have a polygonal shape (e.g., a triangular shape, a rectangular shape, or an oval shape).

FIG. 4 is a cross-sectional view of a semiconductor memory device taken along a line IV-IV′ of FIG. 1. FIG. 5 is a cross-sectional view of a semiconductor memory device taken along a line V-V′ of FIG. 1.

Referring to FIG. 4, the leaf spring 130 and the PCB 110 may be coupled to each other through the solder layer 140 interposed between the leaf spring 130 and the PCB 110. For example, the solder layer 140 may be arranged on the pad 133 of the leaf spring 130.

The solder layer 140 may be formed through a reflow process. That is, the solder layer 140 may be formed through a process of placing a solder between the pad 133 of the leaf spring 130 and the PCB 110 and sequentially melting and curing the solder.

The leaf spring 130 may be seated on the first support structure 123 that extends from a surface of the lower case 120a. The first support structure 123 may provide a support surface 123b on which the leaf spring 130 is seated and may have the upper portion 123a that may be inserted into the through hole 137 of FIG. 3 of the leaf spring 130 and the pin hole 113 of the PCB 110.

The support surface 123b of the first support structure 123 may be a plane on which the support plate 131 of the leaf spring 130 may be seated and may have a ring shape. The upper portion 123a of the first support structure 123 may have a shape protruding from the support surface 123b and may be inserted into the through hole 137 of the leaf spring 130 and the pin hole 113 of the PCB 110 to mitigate or prevent the PCB 110 and the leaf spring 130 from shaking in a horizontal direction.

Before the PCB 110 is seated on the first support structure 123, because the hinge 135 is not bent, the support plate 131 and the pad 133 may be placed at the same level. In other words, while the PCB 110 is spaced apart from the first support structure 123 such that a distance between the support plate 131 and a lower surface of the PCB 110 is the same as a height 140h of the solder layer 140.

If the support plate 131 of the leaf spring 130 is seated on the first support structure 123, a load of the PCB 110 may be applied to the leaf spring 130. Thus, the hinge 135 may be bent in a vertical direction, and a lower surface of the support plate 131 may contact the support surface 123b of the first support structure 123 and an upper surface of the support plate 131 may contact the lower surface of the PCB 110. In other words, the PCB 110 may be spaced from the support surface 123b of the first support structure 123 by a distance corresponding to a thickness 131t of the support plate 131. Thus, the thickness 131t of the support plate 131 may be the same as or similar to a thickness of the hinge 135 and a thickness of the pad 133. In some example embodiments, unlike this, the thickness 131t of the support plate 131 may be different from the thickness of the hinge 135 or the thickness of the pad 133.

In some example embodiments, in order for semiconductor memory devices including the PCB 110 having different thicknesses to share the case 120 of FIG. 1 and the connector 160 of FIG. 1, the leaf spring 130 may be fastened to the PCB 110. To share the same connector 160 between different semiconductor memory devices, a distance from a bottom surface of the lower case 120a to an upper surface of the PCB 110 needs to be the same. For convenience of description, the distance from the bottom surface of the lower case 120a to the upper surface of the PCB 110 is referred to as a first height H1 below.

For example, in order for a first semiconductor memory device including a first PCB having a first thickness and a second semiconductor memory device including a second PCB having a second thickness to share the same case and connector, the leaf spring 130 may be fastened to the second PCB such that a distance from the bottom surface of the lower case to an upper surface of the second PCB may have the first height H1 that is the same as that of the first PCB.

The first height H1 may be substantially the same as a sum of a thickness 120at of the lower case 120a, a distance 123t between the support surface 123b of the first support structure 123 and a surface of the lower case 120a, a thickness 131t of the support plate 131, and a thickness 110t of the PCB 110.

If the support plate 131 of the leaf spring 130 is seated on the first support structure 123, the hinge 135 may be bent in a vertical direction due to the load of the PCB 110. Accordingly, the pad 133 may be placed at a lower level than that of the support plate 131, and the upper surface of the support plate 131 may contact the lower surface of the PCB 110 and the lower surface thereof may contact the support surface 123b of the first support structure 123. A material of the leaf spring 130, the number of the leaf springs 130, and/or the height 140h of the solder layer 140 may be appropriately adjusted such that the hinge 135 may be bent due to the load of the PCB 110.

Referring to FIG. 5, the leaf spring 130 may be seated on the second support structure 125 that extends from the surface of the lower case 120a. The second support structure 125 may provide a support surface 125b on which the leaf spring 130 is seated and may have the cavity 125a into which the fastening device 127 (e.g., a screw) may be inserted. The support surface 125b of the second support structure 125 may be a plane on which the support plate 131 of the leaf spring 130 may be seated and may have a ring shape. The through hole 137 of FIG. 3 of the leaf spring 130 and the pin hole 113 of the PCB 110 may be coupled together by the fastening device 127, which passes through the through hole 137 and the pin hole 113 and is received in the cavity 125a.

The upper case 120b and the lower case 120a may be fastened to each other through the fastening device 127. The fastening device 127 may sequentially penetrate into the upper case 120b, the pin hole 113 of the PCB 110, and the through hole 137 of the leaf spring 130, and then may be accommodated in the cavity 125a of the second support structure 125. Although not shown, a screw thread may be formed in the fastening device 127, and a screw thread corresponding to the screw thread of the fastening device 127 may be formed in an inner surface of the second support structure 125 provided by the cavity 125a. A part of the upper case 120b adjacent to an area at which the fastening device 127 is fastened may be curved in order to contact an upper surface of the PCB 110.

If the leaf spring 130 is seated on the support surface 125b of the second support structure 125, the hinge 135 may be bent in a vertical direction due to a load of the PCB 110. Accordingly, the pad 133 may be placed at a lower level than that of the support plate 131, and an upper surface of the support plate 131 may contact a lower surface of the PCB 110 and a lower surface of the support plate 131 may contact the support surface 125b of the second support structure 125. The first height H1 may be the same as or substantially similar to a sum of the thickness 120at of the lower case 120a, a distance 125t between the support surface 125b of the second support structure 125 and a top surface of the lower case 120a, the thickness 131t of the support plate 131, and the thickness 110t of the PCB 110.

In the example embodiments, the leaf spring 130 may be fastened to the PCB 110 by using a surface mounting method that uses the solder layer 140 such that adhesion may be maintained even though the solder layer 140 is exposed to a high temperature. Thus, the leaf spring 130 may be prevented from being separated from the PCB 110 although a high temperature is applied to a semiconductor memory device during a process of manufacturing or using the semiconductor memory device.

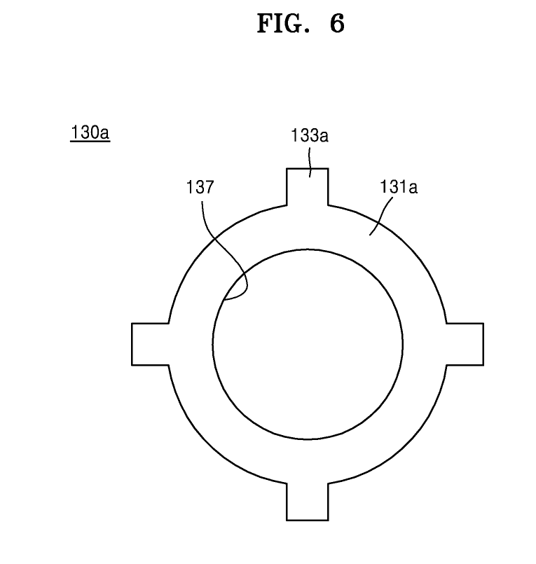

FIG. 6 is a plan view of a leaf spring 130a according to an example embodiment.

Referring to FIG. 6, the leaf spring 130a may include a support plate 131a and a pad 133a. The leaf spring 130a may include one support plate 131a and at least two pads 133a.

The support plate 131a may have the through hole 137 that vertically penetrates therethrough. The through hole 137 of the support plate 131a may be coupled or connected to the pin hole 113 of the PCB 110 of FIG. 2B. The pad 133a may be connected to the support plate 131a in a peripheral direction of the support plate 131a. The solder layer 140 may be arranged on one surface of the pad 133a.

Unlike the leaf spring 130 of FIG. 3, the leaf spring 130a may be configured such that the pad 133a and the support plate 131a may be placed at the same level even when force is applied to the pad 133a. For example, the leaf spring 130a may be a rigid leaf spring.

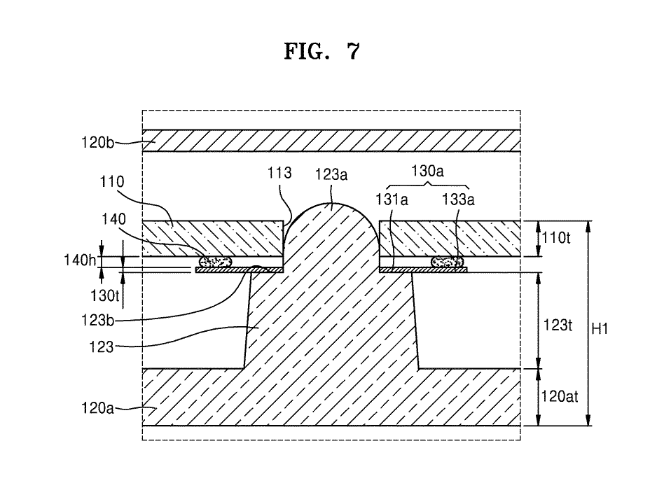

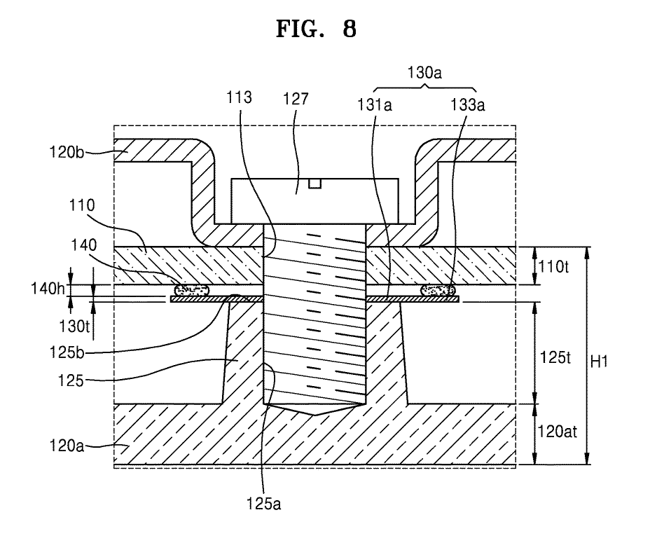

FIG. 7 is a cross-sectional view of a semiconductor memory device taken along a line IV-IV′ of FIG. 1. FIG. 8 is a cross-sectional view of a semiconductor memory device taken along a line V-V′ of FIG. 1. FIGS. 7 and 8 are cross-sectional views of the semiconductor memory device in which the leaf spring 130a described with reference to FIG. 6 is fastened to the PCB 110. The semiconductor memory device shown in FIGS. 7 and 8 may have the same or substantially similar structure as that of the semiconductor memory device shown in FIGS. 4 and 5 except for the leaf spring 130a. The same reference numerals between FIGS. 7 and 8 and FIGS. 4 and 5 denote the same components, and thus detailed descriptions thereof are omitted or briefly provided.

Referring to FIG. 7, the leaf spring 130a and the PCB 110 may be coupled to each other through the solder layer 140 interposed between the leaf spring 130a and the PCB 110. For example, the solder layer 140 may be arranged on the pad 133a of the leaf spring 130a.

The leaf spring 130a may be seated on the first support structure 123 that extends from a surface of the lower case 120a. The first support structure 123 may include the support surface 123b on which the support plate 131a of the leaf spring 130a is seated and the upper portion 123a that may be inserted into the through hole 137 of FIG. 6 of the leaf spring 130a and the pin hole 113 of the PCB 110.

Although the leaf spring 130a is seated on the first support structure 123, the support plate 131a and the pad 133a may be placed at the same level. That is, the PCB 110 may be spaced from the support surface 123b of the first support structure 123 by a distance corresponding to a sum of a thickness 130t of the leaf spring 130a and the height 140h of the solder layer 140. Accordingly, the first height H1 that is a distance from a bottom surface of the lower case 120a to an upper surface of the PCB 110 may be the same as or substantially similar to a sum of the thickness 120at of the lower case 120a, the distance 123t between the support surface 123b of the first support structure 123 and a top surface of the lower case 120a, the thickness 130t of the leaf spring 130a, the height 140h of the solder layer 140, and the thickness 110t of the PCB 110.

Referring to FIG. 8, the leaf spring 130a may be seated on the second support structure 125 that extends from a surface of the lower case 120a. For example, the second support structure 125 may have the support surface 125b, on which the support plate 131a and the pad 133a are seated. The fastening device 127 (e.g., a screw) may pass through the through hole 137 of the leaf spring 130a of FIG. 6 and the pin hole 113 of the PCB 110. Thus, the fastening device 127 may be accommodated in the cavity 125a such that the through hole 137 and the pin hole 113 are communicatively coupled to each other.

If the leaf spring 130a is seated on the support surface 125b of the second support structure 125, the PCB 110 may be spaced apart from the support surface 125b of the second support structure 125 by a distance corresponding to a sum of the thickness 130t of the leaf spring 130a and the height 140h of the solder layer 140. Accordingly, the first height H1 may be substantially the same as a sum of the thickness 120at of the lower case 120a, the distance 125t between the support surface 125b of the second support structure 125 and the top surface of the lower case 120a, the thickness 130t of the leaf spring 130a, the height 140h of the solder layer 140, and the thickness 110t of the PCB 110.

In the example embodiments, the leaf spring 130a may be fastened to the PCB 110 having a relatively small thickness, and the thickness 130t of the leaf spring 130a, and the height 140h of the solder layer 140 may be adjusted, thereby manufacturing a semiconductor memory device including the same connector 160 and the same case 120 although a thickness of the PCB 110 is different.

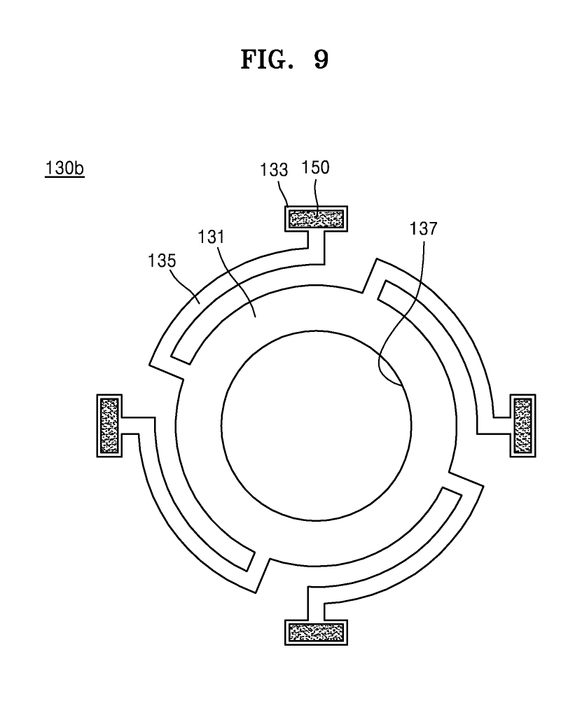

FIG. 9 is a plan view of a leaf spring 130b according to an example embodiment. The leaf spring 130b of FIG. 9 may have the same or substantially similar structure as that of the leaf spring 130 of FIG. 3 except that the leaf spring 130b further includes a first metal layer 150. The same reference numerals between FIGS. 9 and 3 denote the same components, and thus detailed descriptions thereof are omitted or briefly provided.

Referring to FIG. 9, the leaf spring 130b may include the support plate 131, the pad 133, the hinge 135, and the first metal layer 150 included in the pad 133. The first metal layer 150 may be arranged on one surface facing the PCB 110 of FIG. 4 of the pad 133.

The first metal layer 150 may be plated with a conductor on the pad 133, for example, copper. The first metal layer 150 may be connected to the solder layer 140, which is arranged on the pad 133.

In order to bond the leaf spring 130b onto a lower surface of the PCB 110, during a reflow process after placing a solder between the leaf spring 130b and the PCB 110, the first metal layer 150 may be melted at a high temperature and may be stably bonded onto the solder layer 140. For example, when the leaf spring 130b includes a plastic material, the first metal layer 150 may enable the solder layer 140 and the leaf spring 130b stably bonded onto each other.

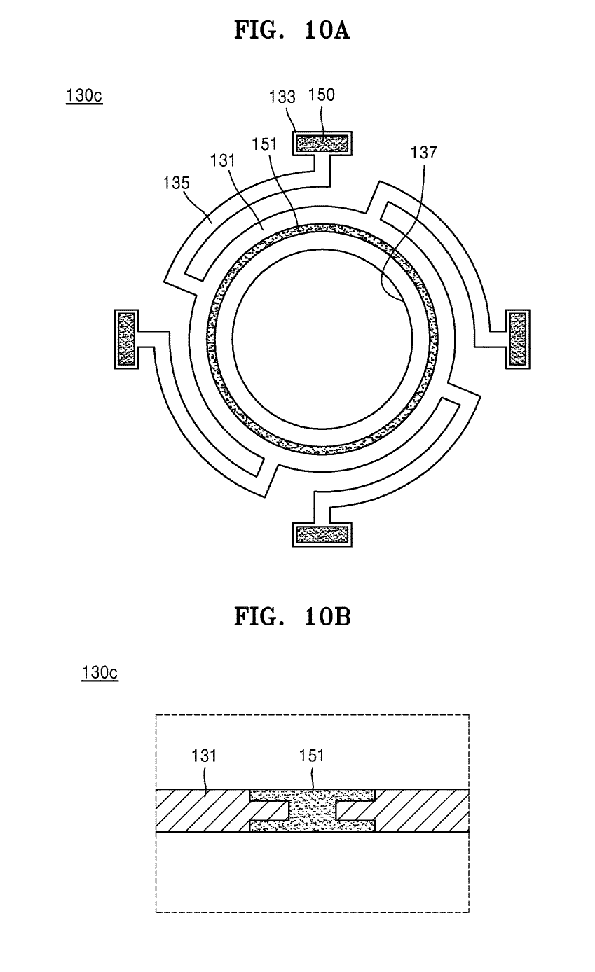

FIG. 10A is a plan view of a leaf spring 130c according to an example embodiment. FIG. 10B is a cross-sectional view of the support plate 131 of the leaf spring 130c of FIG. 10A. The leaf spring 130c of FIGS. 10A and 10B may have the same or substantially similar structure as that of the leaf spring 130b of FIG. 9 except that the leaf spring 130c further includes a second metal layer 151. The same reference numerals between FIGS. 10A and 10B and FIG. 9 denote the same components, and thus detailed descriptions thereof are omitted or briefly provided.

Referring to FIGS. 10A and 10B, the leaf spring 130c may include the support plate 131, the pad 133, the hinge 135, the first metal layer 150 included in the pad 133, and the second metal layer 151 included in the support plate 131.

The second metal layer 151 may vertically penetrate through the support plate 131 of the leaf spring 130c. The second metal layer 151 may be used as an electrical connection path that penetrates into the leaf spring 130c when the leaf spring 130c includes a non-conductive material.

For example, as shown in FIG. 4, the leaf spring 130c may be arranged such that an upper surface of the support plate 131 may contact a lower surface of the PCB 110 and a lower surface of the support plate 131 may contact the support surface 123b of the first support structure 123. Thus, the second metal layer 151 may vertically penetrate through the support plate 131 and may electrically connect the PCB 110 to the first support structure 123.

The second metal layer 151 may electrically connect the PCB 110 to the first support structure 123, thereby providing a path through which electronic waves incident into semiconductor devices included in the PCB 110 are discharged to a case.

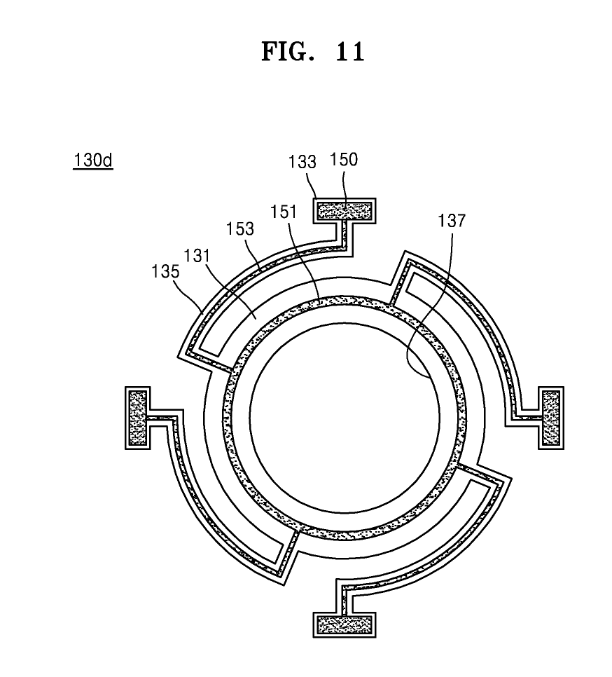

FIG. 11 is a plan view of a leaf spring 130d according to an example embodiment. The leaf spring 130d of FIG. 11 may have the same or substantially similar structure as that of the leaf spring 130c of FIG. 10A except that the leaf spring 130d further includes a third metal layer 153. The same reference numerals between FIGS. 11 and 10A denote the same components, and thus detailed descriptions thereof are omitted or briefly provided.

Referring to FIG. 11, the leaf spring 130d may include the support plate 131, the pad 133, the hinge 135, the first metal layer 150 included in the pad 133, the second metal layer 151 included in the support plate 131, and the third metal layer 153 extending along the hinge 135.

The third metal layer 153 may be arranged over the hinge 135, a part of the support plate 131, and a part of the pad 133 and may connect the first metal layer 150 to the second metal layer 151.

The third metal layer 153 may vertically penetrate through the hinge 135, a part of the support plate 131, and a part of the pad 133. However, example embodiments are not limited thereto.

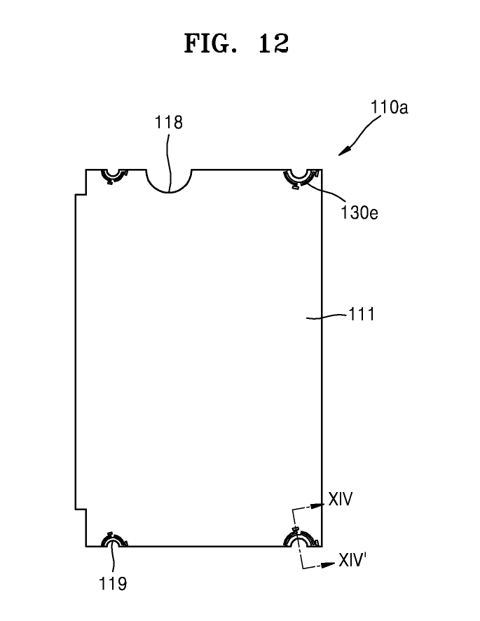

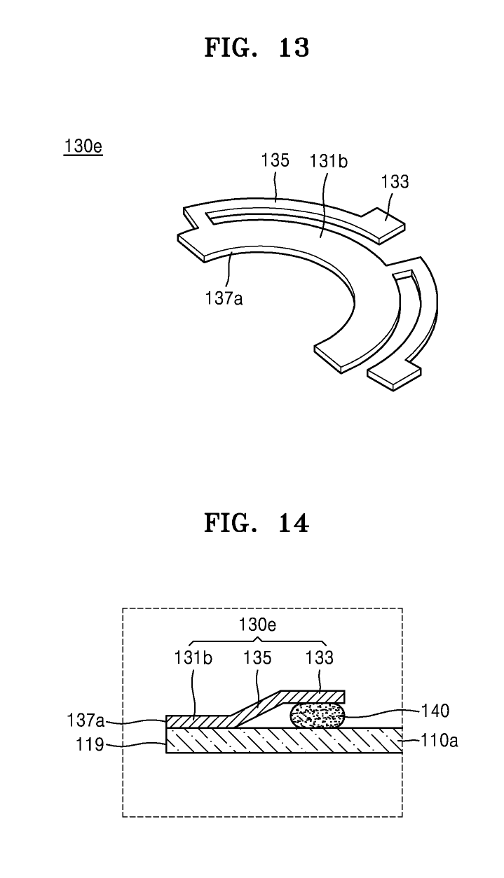

FIG. 12 is a plan view of a lower surface of a PCB 110a according to an example embodiment. FIG. 13 is a perspective view of a leaf spring 130e of FIG. 12. FIG. 14 is a cross-sectional view of the PCB 110a taken along a line XIV-XIV′ of FIG. 12.

The PCB 110a of FIG. 12 may have the same or substantially same structure as that of the PCB 110 of FIGS. 1 through 2B except that the PCB 110a includes a groove (e.g., semicircular pin hole) 119 instead of a pin hole having a circular shape. The leaf spring 130e of FIG. 13 may have the same or substantially similar structure as that of the leaf spring 130 of FIG. 3 except that the leaf spring 130e includes a groove (e.g., semicircular through hole) 137a other than a through hole having a circular shape and except for a structure of the leaf spring 130e. The same reference numerals between FIGS. 12 through 14 and FIGS. 1 through 3 denote the same components, and thus detailed descriptions thereof are omitted or briefly provided.

Referring to FIGS. 12 and 13, the PCB 110a may include the grooves 119 arranged in edges thereof. The grooves 119 may have a shape that vertically penetrates through the PCB 110a when viewed from above. For example, the grooves 119 may be provided in two for each of both opposite edges of the PCB 110a. However, the arrangement and number of the grooves 119 according to example embodiments are not limited thereto.

The leaf spring 130e may include a support plate 131b, at least one pad 133, and at least one hinge 135b. The support plate 131b may include the groove 137a. The support plate 131b may have a partially cut disc shape. When viewed from above, the groove 137a of the support plate 131b may vertically penetrate through the support plate 131b. The groove 137a of the support plate 131b may have a shape corresponding to the groove 119 of the PCB 110a.

The groove 119 of the PCB 110a and the groove 137a of the support plate 131b may accommodate a part of the upper portion 123a of the first support structure 123 of FIG. 4. In some example embodiments, the groove 119 of the PCB 110a and the groove 137a of the support plate 131b may be connected to the cavity 125a of the second support structure 125 of FIG. 5. A fastening device may pass through the groove 119 of the PCB 110a and the groove 137a of the support plate 131b and may be inserted into the cavity 125a of the second support structure 125 of FIG. 5. When the leaf spring 130e is seated on the first support structure 123 of FIG. 4 and/or the second support structure 125 of FIG. 5, the hinge 135 may be bent in a vertical direction. Thus, a distance between the support surface 123b of the first support structure 123 of FIG. 4 and a lower surface of the PCB 110a may be substantially the same as a thickness of the support plate 131b.

Referring to FIG. 14, the solder layer 140 may be interposed between the PCB 110a and the pad 133 of the leaf spring 130e to allow the leaf spring 130e to be fastened to the PCB 110a. FIG. 14 illustrates that two pads 133 are provided to one leaf spring 130e. However, example embodiments are not limited thereto.

If a load of the PCB 110a is applied to the leaf spring 130e, the hinge 135 of the leaf spring 130e may be bent in a vertical direction, and thus an upper surface of the support plate 131b may contact a lower surface of the PCB 110a, and although not shown, a lower surface thereof may contact the support surface 123b of the first support structure 123 of FIG. 4 or the support surface 125b of the second support structure 125 of FIG. 5.

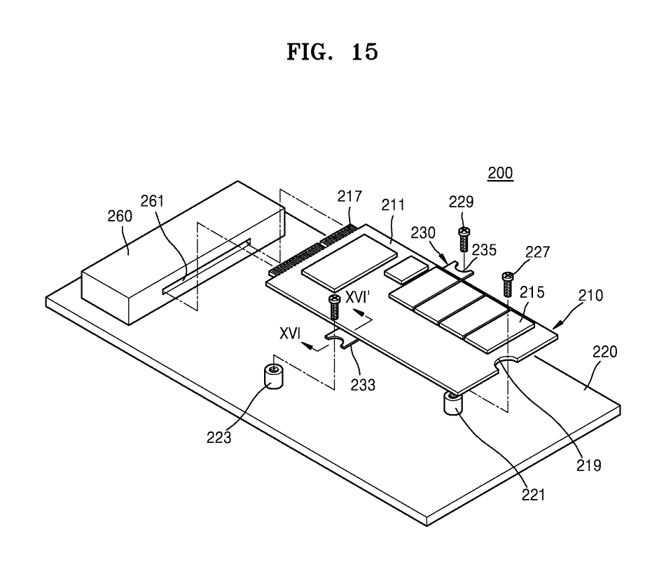

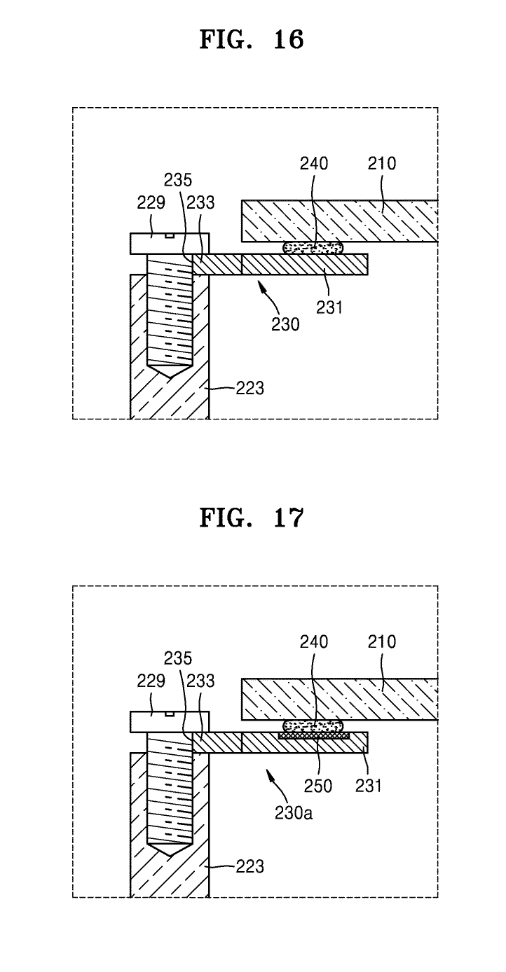

FIG. 15 is a schematic perspective view of a semiconductor memory device 200 according to an example embodiment. FIG. 16 is a cross-sectional view of the semiconductor memory device 200 taken along a line XVI-XVI′ of FIG. 15.

Referring to FIG. 15, the semiconductor memory device 200 may include a case 220, a PCB 210 and a connector 260 that are installed in the case 220, and at least one leaf spring 230 fastened to the PCB 110. The PCB 210 may include a body 211 forming an exterior thereof, a semiconductor device 215, and connection terminals 217.

The PCB 210 may include the connection terminals 217 arranged along one edge thereof. A leading portion of the PCB 210 in which the connection terminals 217 are arranged may be inserted into the connector 260 such that the connection terminals 217 are connected to internal wirings (not shown) of the connector 260. In this regard, the connector 260 may have a socket portion 261 that is configured to accommodate the leading portion of the PCB 210. The leading portion of the PCB 210 may be supported by the connector 260 when accommodated in the socket portion 261.

The PCB 210 may include a first groove 219 for adhering the PCB 210 to the case 220. The first groove 219 may be arranged in a rear portion opposite to the leading portion. The PCB 210 may be seated on a PCB support structure 221 such that the first groove 219 is placed on the PCB support structure 221, which extends from a surface of the case 220. A PCB fastening device 227 may pass through the first groove 219, may be inserted into the PCB support structure 221, and may press an upper surface of the PCB 210, thereby adhering the PCB 210 to the case 220.

The PCB 210 may include the at least one semiconductor device 215 mounted on one surface thereof and the connection terminals 217 arranged along one edge thereof. The semiconductor device 215 and the connection terminals 217 are described in detail with reference to FIGS. 1 through 2B, and thus redundant descriptions thereof are omitted.

The leaf spring 230 may be mounted on a surface of the PCB 210 and may be arranged in an edge of the PCB 210.

As shown in FIG. 15, the leaf spring 230 may be arranged in each of both opposite edges of the PCB 210. However, example embodiments are not limited thereto. The two or more leaf springs 230 may be arranged in each edge of the PCB 210.

As shown in FIG. 15, the leaf spring 230 may be arranged at a center portion of one edge of the leaf spring 230. However, methods of placing the leaf spring 230 according to example embodiments are not limited thereto. For example, a location of the leaf spring 230 may be arranged adjacent to a corner portion of the PCB 210. The leaf spring 230 may be arranged in one edge of the PCB 210 in which a second groove 235 is arranged.

A part of the leaf spring 230 may protrude in a peripheral direction of the PCB 210. The part of the leaf spring 230 protruding in the peripheral direction of the PCB 210 may be adhered to the case 220. For example, the leaf spring 230 protruding in the peripheral direction of the PCB 210 may be seated on a leaf spring support structure (interchangeably, support structure) 223 extending from a surface of the case 220. The second groove 235 may be formed in one side of the leaf spring 230. The leaf spring fastening device 229 may pass through the second groove 235 and may be accommodated in a cavity of the leaf spring support structure 223. The leaf spring fastening device 229 may press at least a part of the leaf spring 230 such that the leaf spring 230 is adhered to the leaf spring support structure 223.

Referring to FIG. 16, a solder layer 240 may be interposed between the leaf spring 230 and the PCB 210 and may couple the leaf spring 230 and the PCB 210. The solder layer 240 may be formed by placing a solder between the leaf spring 230 and the PCB 210 and then a reflow process of sequentially melting and curing the solder.

The leaf spring 230 may be connected to a first plate 231 providing one surface on which the solder layer 240 is arranged and a second plate 233 connected to the first plate 231, protruding in a peripheral direction of the PCB 210, and adhered to the leaf spring support structure 223.

In some example embodiments, the leaf spring 230 may enhance rigidity of the PCB 210, thereby reducing damage of the PCB 210 due to an external shock.

Because the leaf spring 230 is fastened to the PCB 210, rigidity of the PCB 210 may be enhanced, and thus an intrinsic frequency of the PCB 210 may increase. An arrangement, number, shape, and material of the leaf spring 230 may be appropriately adjusted, and thus the intrinsic frequency of the PCB 210 may be adjusted to avoid a resonance frequency. For example, a main resonance frequency that causes resonance of a portable electronic device (e.g., a laptop computer) may be less than 500 Hz. Thus, an intrinsic resonance frequency of the PCB 210 may be configured to exceed 500 Hz by fastening the leaf spring 230 to the PCB 210, thereby mitigating or preventing the semiconductor memory device 200 from being damaged due to resonance.

FIG. 17 is a cross-sectional view of the semiconductor memory device taken along a line XVI-XVI′ of FIG. 15 according to an example embodiment.

The semiconductor memory device shown in FIG. 17 may have the same or substantially similar structure as that of the semiconductor memory device shown in FIG. 16 except that the leaf spring 230a further includes a first metal layer 250. The same reference numerals between FIGS. 17 and 16 denote the same components, and thus detailed descriptions thereof are omitted or briefly provided.

Referring to FIG. 17, the leaf spring 230a may include the first plate 231 and the second plate 233 and the first metal layer 250 provided on the first plate 231. The first metal layer 250 may be plated with a conductor on the first plate 231. The first metal layer 250 may be connected to the solder layer 240 arranged on the first plate 231. For example, when the leaf spring 230a includes a plastic material, the first metal layer 250 may allow the solder layer 240 to be stably bonded to the leaf spring 230a.

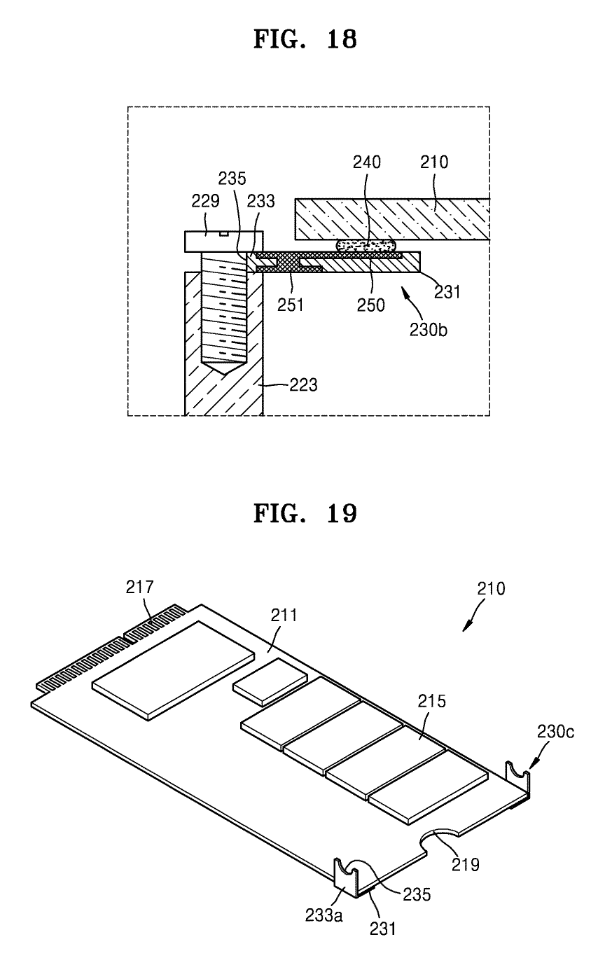

FIG. 18 is a cross-sectional view of the semiconductor memory device taken along a line XVI-XVI′ of FIG. 15 according to an example embodiment.

The semiconductor memory device shown in FIG. 18 may have the same or substantially similar structure as that of the semiconductor memory device shown in FIG. 17 except that the leaf spring 230b further includes a second metal layer 251. The same reference numerals between FIGS. 18 and 17 denote the same components, and thus detailed descriptions thereof are omitted or briefly provided.

Referring to FIG. 18, the leaf spring 230b may include the first plate 231 and the second plate 233, the first metal layer 250 provided on the first plate 231, and the second metal layer 251 connecting the first metal layer 250 and the leaf spring support structure 223.

When the leaf spring 230b includes a non-conductive material, the second metal layer 251 may be used as an electrical connection path that electrically connects the PCB 210 and the leaf spring support structure 223. For example, the PCB 210 and the leaf spring support structure 223 may be electrically connected to each other through the solder layer 240, the first metal layer 250, and the second metal layer 251.

The first metal layer 250 and the second metal layer 251 may electrically connect the PCB 210 to the leaf spring support structure 223, thereby providing a path through which electronic waves incident into semiconductor devices included in the PCB 210 are discharged to the case 220 of FIG. 15.

FIG. 19 is a plan view of a PCB 210 according to an example embodiment. The PCB 210 of FIG. 19 may have the same or substantially similar structure as that of the PCB 210 of FIGS. 15 and 16 except for a shape of a leaf spring 230c. The same reference numerals between FIG. 19 and FIGS. 15 and 16 denote the same components, and thus detailed descriptions thereof are omitted or briefly provided.

Referring to FIG. 19, the leaf spring 230c may have a curved shape. For example, the leaf spring 230c may include a first plate 231 and a second plate 233a. The second plate 233a may extend in an inclined direction from a direction in which the first plate 231 extends. For example, the first plate 231 and the second plate 233a may be perpendicular to each other.

The leaf spring 230c having the curved shape may be prevented from being separated from the PCB 210 during a reflow process. For example, during the reflow process, the leaf spring 230c may be placed on a surface of the PCB 210 with a solder between the leaf spring 230c and the PCB 210. A part of the leaf spring 230c may protrude in a peripheral direction of the PCB 210. If a weight center of the leaf spring 230c is not placed inside the PCB 210, the leaf spring 230c may be separated from the PCB 210. Thus, the leaf spring 230c may be curved by placing the weight center of the leaf spring 230c inside the PCB 210, thereby mitigating or preventing the leaf spring 230c from moving or being separated from the PCB 210 during the reflow process.

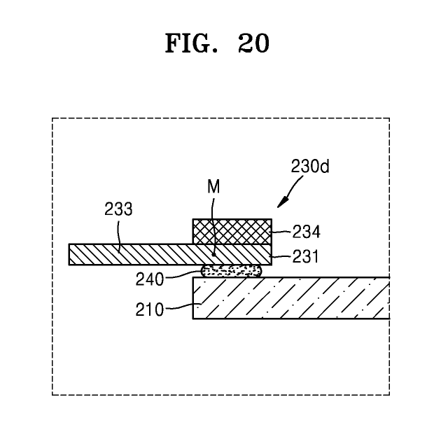

FIG. 20 is a cross-sectional view of a part of a semiconductor memory device according to an example embodiment.

The semiconductor memory device of FIG. 20 may have the same or substantially similar structure as that of the semiconductor memory device 200 of FIGS. 15 and 16 except that a leaf spring 230d further includes a dummy mass 234. The same reference numerals between FIG. 20 and FIGS. 15 and 16 denote the same components, and thus detailed descriptions thereof are omitted or briefly provided. For convenience of description, contrary to a lower surface of the PCB 210 facing down in FIGS. 15 and 16, the lower surface of the PCB 210 is illustrated to face up in FIG. 20.

Referring to FIG. 20, the leaf spring 230d may further include the dummy mass 234 provided to place a weight center M of the leaf spring 230d on the PCB 210. The dummy mass 234 may be arranged opposite to the solder layer 240 with respect to the first plate 231. The dummy mass 234 may be arranged in a region where at least a part of the dummy mass 234 overlaps with the PCB 210 in a vertical direction.

The leaf spring 230d may contact a solder arranged on the PCB 210 in order to perform a reflow process. The weight center M of the leaf spring 230d including the dummy mass 234 may be placed on the PCB 210, thereby mitigating or preventing the leaf spring 230d from being separated from the PCB 210 during the reflow process.

The dummy mass 234 may have a desired (or alternatively, predetermined) amount of mass suitable for adjusting the weight center M of the leaf spring 230d to a set location and may have various materials and/or shapes. The dummy mass 234 may be fixed to a part of the leaf spring 230d by using various methods. For example, the dummy mass 234 may be attached to the first plate 231 by using an adhesive or by using a fixer (e.g., a hook structure) provided on the first plate 231.

While the inventive concepts have been particularly shown and described with reference to some example embodiments thereof, it will be understood that various changes in form and details may be made therein without departing from the spirit and scope of the following claims.

1. A printed circuit board (PCB) comprising:
a body;
at least one leaf spring coupled to the body, and
a solder layer between the body and the at least one leaf spring, the solder layer coupling the at least one leaf spring with the body.

2. The PCB of claim 1, wherein the at least one leaf spring comprises:
a support plate facing one surface of the body; and
a pad connected to the support plate, the pad along a periphery of the support plate, the pad having the solder layer thereon.

3. The PCB of claim 2, wherein the at least one leaf spring further comprises a hinge connecting the support plate to the pad, the hinge extending from at least a part of an edge of the support plate.

4. The PCB of claim 2, wherein
the body comprises a pin hole vertically penetrating therethrough; and
the support plate of the at least one leaf spring include a through hole vertically penetrating therethrough, the through hole communicatively connected to the pin hole.

5. The PCB of claim 1, wherein the at least one leaf spring comprises:
a first plate having the solder layer thereon; and
a second plate connected to the first plate, the second plate protruding along a periphery of the body, the second plate having a groove at one side thereof.

6-7. (canceled)

8. The PCB of claim 1, wherein the at least one leaf spring comprises a plastic material.

9. The PCB of claim 8, wherein the at least one leaf spring further comprises a first metal layer on the pad, the first metal layer contacting the solder layer.

10. The PCB of claim 8, wherein the at least one leaf spring further comprises a second metal layer vertically penetrating therethrough.

11. A semiconductor memory device comprising:
a case;
a printed circuit board (PCB) in the case;
at least one leaf spring coupled onto a lower surface of the PCB; and
a solder layer between the PCB and the at least one leaf spring, the solder layer coupling the PCB with the at least one leaf spring.

12. The semiconductor memory device of claim 11, wherein
the case comprises support structures supporting the PCB,
the at least one leaf spring is between the PCB and the support structures, and
the PCB and the support structures are spaced apart from each other by the at least one leaf spring interposed therebetween.

13-17. (canceled)

18. The semiconductor memory device of claim 11, wherein the at least one leaf spring comprises:
a first plate having the solder layer thereon; and
a second plate connected to the first plate, the second plate protruding in a peripheral direction of the PCB, the second plate coupled to the case.

19-21. (canceled)

22. The semiconductor memory device of claim 11, wherein the at least one leaf spring comprises a plastic material.

23-30. (canceled)

31. A semiconductor memory device comprising:
a case including a supporting structure, the supporting structure extending from one surface of the case;
a printed circuit board (PCB) in the case, the PCB including a top surface and a bottom surface, the top surface of the PCB having a semiconductor device thereon, the bottom surface of the PCB facing and supported by the support structure;
a leaf spring between the bottom surface of the PCB and the support structure, the leaf spring having a first portion vertically overlapping the support structure and a second portion not vertically overlapping the support structure; and
a solder layer between the PCB and the second portion of the leaf spring, the solder layer coupling the PCB with the leaf spring.

32. The semiconductor memory device of claim 31, wherein the leaf spring is bent such that the second portion of the leaf spring is placed at a lower level than the first portion of the leaf spring.

33. The semiconductor memory device of claim 31, wherein
the leaf spring comprises a through hole or groove vertically penetrating the first portion therethrough;
the PCB is coupled to the second portion of the leaf spring using the solder layer, and
the first portion of the leaf spring is coupled with the support structure using a fastener passing through both the through hole and accommodated in a cavity defined in the support structure.

34. The semiconductor memory device of claim 31, wherein the support structure comprises at least one of a protruded upper portion or a cavity defined therein.

35. The semiconductor memory device of claim 34, wherein
the PCB comprises a pin hole vertically penetrating therethrough,
the leaf spring comprises a through hole vertically penetrating therethrough, and
the PCB is coupled to the support structure by one of the protruded upper portion passing through the pin hole and the through hole or a fastener passing through both the pin hole and the through hole and accommodated in the cavity.

36. The semiconductor memory device of claim 31, wherein leaf spring further comprises a first metal layer on the second portion, the first metal layer contacting the solder layer.

37. The semiconductor memory device of claim 31, wherein the leaf spring further comprises a second metal layer embedded in the first portion in a vertically penetrating manner such that the second metal layer contacts the bottom surface of the PCB and a leaf spring support surface of the support structure.

38. The semiconductor memory device of claim 31, wherein the leaf spring further comprises a dummy mass, the dummy mass arranged opposite to the solder layer with respect to the second portion, the dummy mass being at a region where at least a part of the dummy mass overlaps with the PCB in a vertical direction.
